(19) United States
(12) Patent Application Publication
(10) Pub. No.: US 2012/0175156 A1
(43) Pub. Date: Jul. 12, 2012

(54) PRINTED CIRCUIT BOARD

(75) Inventor: CHANG-XIN HUANG, Taipei City (TW)

(73) Assignee: CHUNGHWA PICTURE TUBES, LTD., Bade City (TW)

(21) Appl. No.: 13/088,297

(22) Filed: Apr. 15, 2011

(30) Foreign Application Priority Data
Jan. 10, 2011 (TW) 100200517

(51) Int. Cl. H05K 1/09; H05K 1/02

(52) U.S. Cl. 174/257; 174/256

(57) ABSTRACT

A printed circuit board includes a substrate, a plurality of metal wires, and a solder mask layer. The substrate includes a first area and a second area. The second area surrounds and does not overlap the first area. The metal wires are disposed on the first area of the substrate. One end of one of two adjacent metal wires faces one end of the other one of the two adjacent metal wires. The solder mask layer is formed on the second area of the substrate. In the present invention, a short circuit or an open circuit between the two adjacent metal wires is directly formed during processes of manufacturing the printed circuit board, whereby a jumper is not required so as to reduce a layout area, and cost of a manual post-welding treatment can be reduced.

### BACKGROUND OF THE INVENTION

1. Field of the Invention

The present invention generally relates to a printed circuit board (PCB), and more particularly to a printed circuit board which is capable of reducing a layout area.

2. Description of Prior Art

Please refer to FIGS. 1A-1C, which illustrate steps of a process for manufacturing a printed circuit board in the prior art. As shown in FIG. 1A, a plurality of metal wires 102 are formed on a substrate 100, and a solder mask layer 104 covers an area on the substrate 100 excluding the metal wires 102, that is, the solder mask layer 104 does not cover the metal wires 102. Then, as shown in FIG. 1B, a solder paste 108 is coated using a screen 106 so that the solder paste 108 is only applied on the metal wires 102 but not the solder mask layer 104. Finally, as shown in FIG. 1C, after the screen 106 is removed and the solder paste 108 is heated by a soldering pot (not shown), the melted solder paste 108 is coagulated to form a solder layer 110. The solder layer 110 is formed only on the metal wires 102 but not formed on the solder mask layer 104.

Since two adjacent metal wires 102 are separated by the solder mask layer 104 and portions of the solder layer 110 on the two adjacent metal wires 102 are electrically disconnected with each other, an open circuit is formed between the two adjacent metal wires 102.

When the two adjacent metal wires 102 are required to be short-circuited , a jumper 112 is utilized to electrically couple the two adjacent metal wires 102 so that the two adjacent metal wires 102 are short-circuited, as shown in FIG. 2. The jumper 112 usually has a resistance value of zero ohm or a small resistance value, so that the two adjacent metal wires 102 can be short-circuited through the jumper 112. Although a number of times for redesigning a layout of the printed circuit board can be effectively reduced by using the jumper 112, however, a greater layout area will be occupied when a number of the jumpers 112 is increased.

Please refer to FIG. 3, which illustrates another method to form a short circuit between the two adjacent metal wires 102 by a post-welding treatment. As shown in FIG. 3, another solder layer 114 is manually formed by the post-welding treatment so as to electrically couple the two adjacent metal wires 102. However, labor cost is increased due to the post-welding treatment.

Therefore, there is a need to solve the above-mentioned problems occurring in using the jumpers and the post-welding treatment.

### SUMMARY OF THE INVENTION

An objective of the present invention is to provide a printed circuit board which is capable of reducing jumpers so as to reduce a layout area.

According to an aspect of the present invention, the printed circuit board comprises a substrate, a plurality of metal wires, and a solder mask layer. The substrate comprises a first area and a second area. The second area surrounds and does not overlap the first area. The metal wires are disposed on the first area of the substrate. One end of one of two adjacent metal wires faces one end of the other one of the two adjacent metal wires. The solder mask layer is formed on the second area of the substrate.

In the present invention, a short circuit or an open circuit between the two adjacent metal wires is directly formed during steps of a process for manufacturing the printed circuit board. Accordingly, the jumper or the post-welding treatment is not required after the printed circuit board is manufactured, and therefore a reduction of the jumper being used so as to reduce the layout area as well as reducing labor cost of the post-welding treatment can be achieved.

### BRIEF DESCRIPTION OF THE DRAWINGS

FIGS. 1A-1C illustrate steps of a process for manufacturing a printed circuit board in the prior art;

FIG. 2 illustrates that a jumper is utilized to electrically couple the two adjacent metal wires;

FIG. 3 illustrates another method to form a short circuit between the two adjacent metal wires by a post-welding treatment;

FIGS. 4A-4D illustrate four layout models between the two adjacent metal wires according to the present invention;

FIGS. 5A-5C illustrate steps of a process for manufacturing a printed circuit board according to the present invention;

FIG. 6 illustrates a vertical view of the printed circuit board;

FIGS. 7A-7C illustrate steps of a process for manufacturing a printed circuit board according to the present invention; and

FIG. 8 illustrates a vertical view of the printed circuit board.

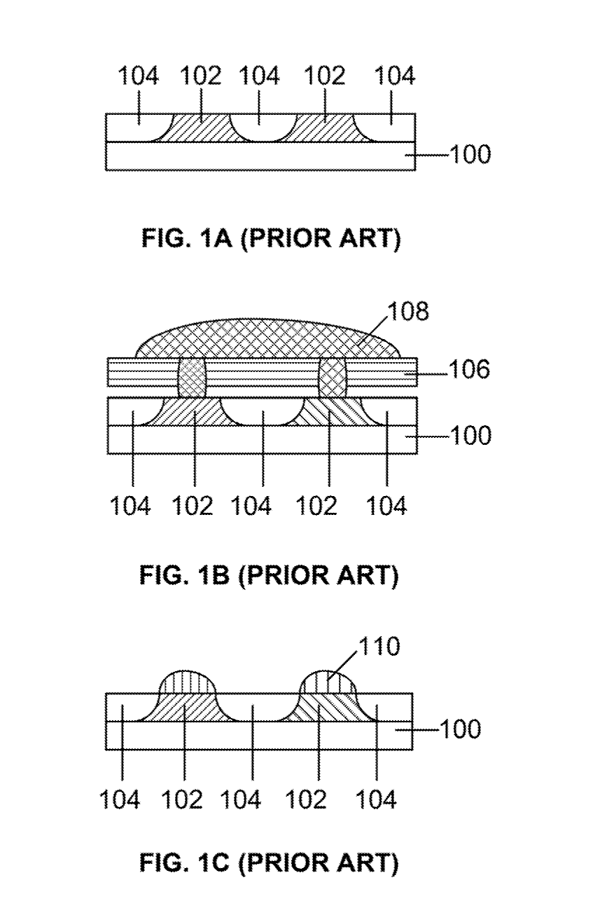

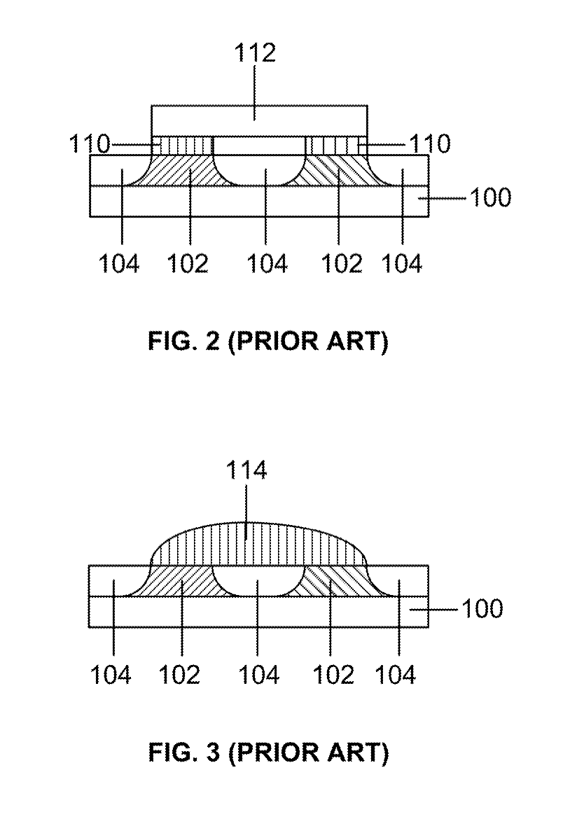

### DETAILED DESCRIPTION OF THE INVENTION

As everyone knows, a short circuit or an open circuit between two adjacent metal wires is determined before a printed circuit board is made. In the prior art, the short circuit between the two adjacent circuit metal wires is implemented by a jumper or a post-welding treatment after the printed circuit board is manufactured. In the present invention, the short circuit or the open circuit between the two adjacent metal wires is implemented during steps of a process for manufacturing the printed circuit board.

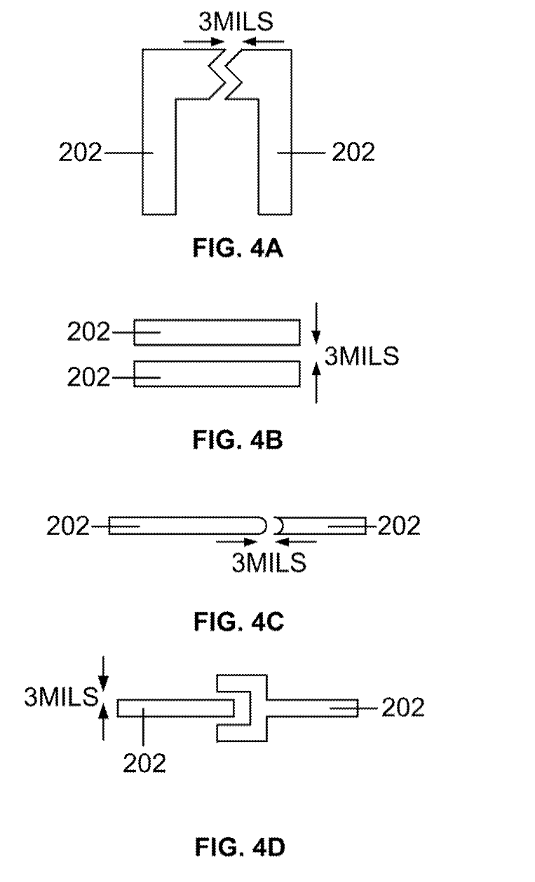

Before manufacturing the printed circuit board, a layout step is required first. The present invention provides four layout models for two adjacent metal wires 202 as shown in FIGS. 4A-4D. In FIG. 4A, one end of one of two adjacent metal wires 202 faces one end of the other one of the two adjacent metal wires 202. The one end of one of the two adjacent metal wires 202 and the one end of the other one of the two adjacent metal wires 202 are jagged. In FIG. 4B, one end of one of two adjacent metal wires 202 faces one end of the other one of the two adjacent metal wires 202. The one end of one of the two adjacent metal wires 202 and the one end of the other one of the two adjacent metal wires 202 are rectangular. In FIG. 4C, one end of one of two adjacent metal wires 202 faces one end of the other one of the two adjacent metal wires 202. The one end of one of the two adjacent metal wires 202 is convex, and the one end of the other one of the two adjacent metal wires 202 is concave. In FIG. 4D, one end of one of two adjacent metal wires 202 faces one end of the other one of the two adjacent metal wires 202. The one end of one of the two adjacent metal wires 202 is rectangular, and the one end of the other one of the two adjacent metal wires 202 is in a form of a “C” to embrace the rectangular end. However, no matter which one of the four layout models is utilized, a distance between the two adjacent metal wires 202 is equal to or greater than 3 mils so as to prevent the two adjacent metal wires 202 from being formed a short circuit in a normal situation. The adjacent metal wires 202 are made of one material selected from a group consisting of copper, tin, nickel, titanium, and chromium.

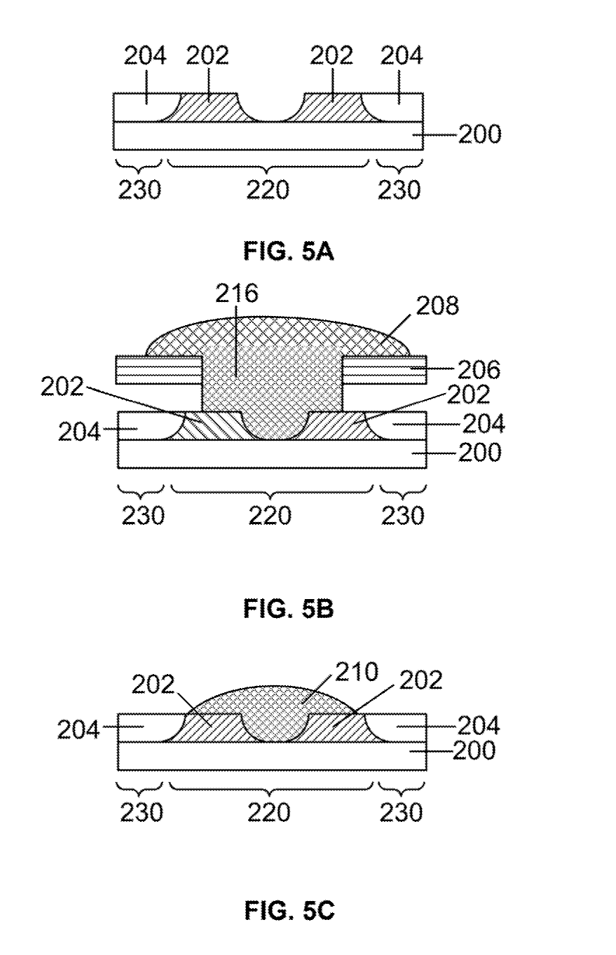

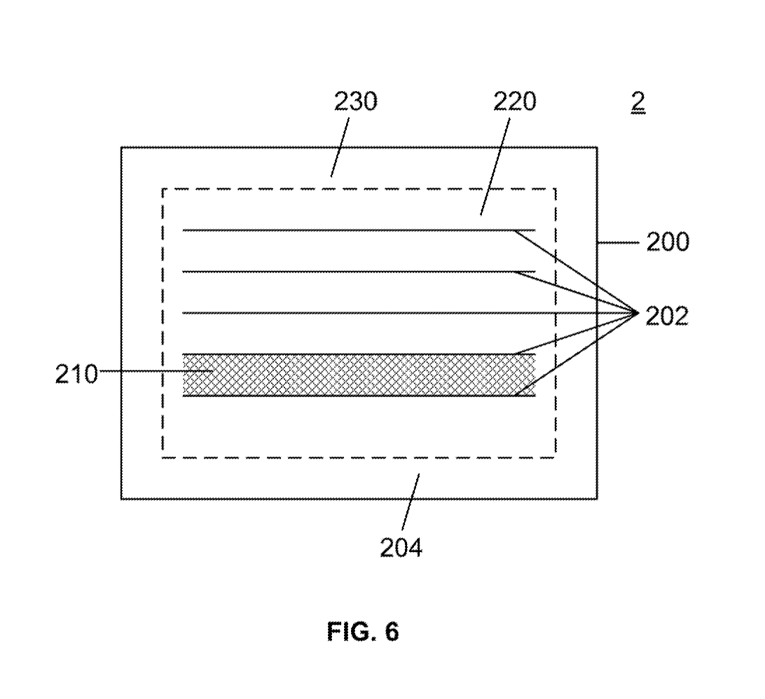

After the layout step is finished, steps of a process for manufacturing a printed circuit board 2 according to the present invention are shown in FIGS. 5A-5C and FIG. 6. FIG. 6 illustrates a vertical view of the printed circuit board 2. In a pattering step as shown in FIG. 5A, a substrate 200 which comprises a first area 220 and a second area 230 is provided. Plural metal wires 202 are disposed on the first area 220 of the substrate 200. A solder mask layer 204 is formed on the second area 230 of the substrate 200. In the present embodiment, the second area 230 surrounds and does not overlap (i.e. without overlapping) the first area 220. It is noted that the present invention differs from the prior art in that the solder mask layer 204 of the present invention is not formed on the first area 220.

Then, in a step of coating a solder paste 208 as shown in FIG. 5B, if two adjacent metal wires 202 are required to be short-circuited, the solder paste 208 is coated by using a screen 216 having an opening so that the solder paste 208 covers the two adjacent metal wires 202 on the first area 220 for electrically coupling the two adjacent metal wires 202.

Finally, as shown in FIG. 5C, after the screen 206 is removed and the solder paste 208 is heat by a soldering pot (not shown), so that the melted solder paste 208 is coagulated to form a solder layer 210 (i.e. an electrically-conductive layer). The solder layer 210 is formed both on the two adjacent metal wires 202 and portions between the two adjacent metal wires 202, whereby the short circuit is formed between the two adjacent metal wires 202. The solder layer 210 is made of one material selected from a group consisting of tin (Sn), tin-lead (Sn—Pb), tin-copper (Sn—Cu), tin-silver (Sn—Ag), and tin-silver-copper (Sn—Ag—Cu).

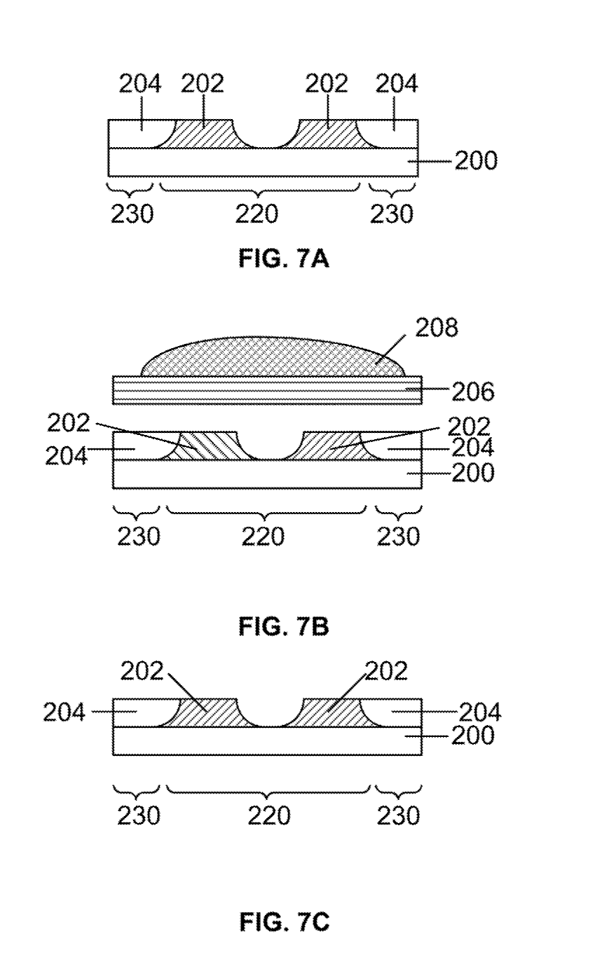

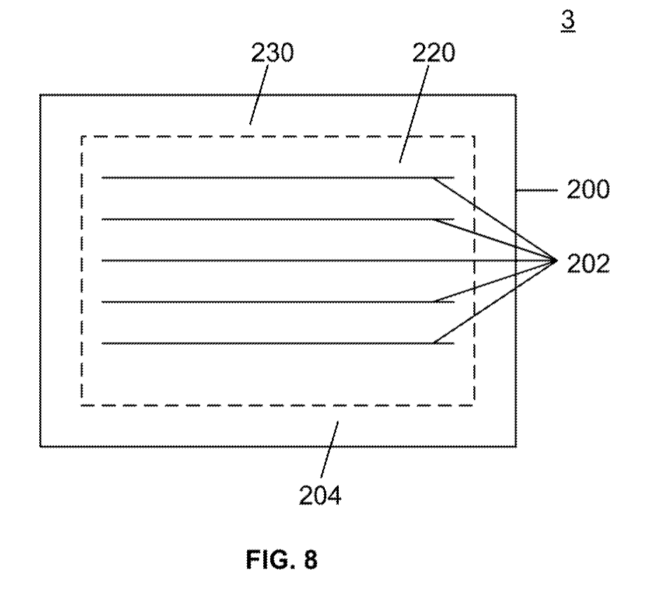

Please refer to FIGS. 7A-7C and FIG. 8. FIGS. 7A-7C illustrate steps of a process for manufacturing a printed circuit board 3 according to the present invention. FIG. 8 illustrates a vertical view of the printed circuit board 3. In a patterning step as shown in FIG. 7A, a substrate 200 which comprises a first area 220 and a second area 230 is provided. The same as in FIG. 5A, plural metal wires 202 are disposed on the first area 220 of the substrate 200. A solder mask layer 204 is formed on the second area 230 of the substrate 200. In the present embodiment, the second area 230 surrounds and does not overlap (i.e. without overlapping) the first area 220. It is noted that the present invention differs from the prior art in that the solder mask layer 204 is not formed on the first area 220 in the present invention.

Then, in a step of coating a solder paste 208 as shown in FIG. 7B, if two adjacent metal wires 202 are required to be open-circuited, the solder paste 208 is coated by using a screen 216 not having an opening so that the solder paste 208 does not cover the two adjacent metal wires 202 and portions between the two adjacent metal wires 202. It is noted that when the open circuit is formed between the two adjacent metal wires 202, the present invention differs from the prior art in that the solder past 208 does not cover the first area 220 in the present invention.

Finally, as shown in FIG. 7C, the screen 206 is removed, and the solder paste 208 is heated by a soldering pot (not shown). Since the solder paste 208 does not cover the first area 220, the solder layer 210 shown in FIG. 5C is not formed in FIG. 7C. Accordingly, the open circuit is formed between the two adjacent metal wires 202.

In summary, the short circuit or the open circuit between the two adjacent metal wires 202 is already determined before the layout step, and the short circuit or the open circuit can be formed during the steps of the process for manufacturing the printed circuit board in accordance with the present invention. After the printed circuit board is finished being manufactured, a jumper or a post-welding treatment is not required for forming the short circuit. Accordingly, a layout area can be reduced because the jumper is not required, and labor cost of the post-welding treatment can be reduced as well. Furthermore, when the open circuit is formed between the two adjacent metal wires 202, the solder paste 208 does not cover the two adjacent metal wires 202 and thus cost of forming the solder paste 208 can be reduced.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A printed circuit board comprising:
a substrate comprising a first area and a second area, the second area surrounding and without overlapping the first area;
a plurality of metal wires disposed on the first area of the substrate, wherein one end of one of two adjacent metal wires faces one end of the other one of the two adjacent metal wires; and
a solder mask layer formed on the second area of the substrate.

2. The printed circuit board as claimed in claim 1, wherein an electrically-conductive layer is formed on the two adjacent metal wires on the first area for electrically coupling the two adjacent metal wires.

3. The printed circuit board as claimed in claim 1, wherein the one end of one of the two adjacent metal wires and the one end of the other one of the two adjacent metal wires are jagged.

4. The printed circuit board as claimed in claim 1, wherein the one end of one of the two adjacent metal wires and the one end of the other one of the two adjacent metal wires are rectangular.

5. The printed circuit board as claimed in claim 1, wherein the one end of one of the two adjacent metal wires is convex, and the one end of the other one of the two adjacent metal wires is concave.

6. The printed circuit board as claimed in claim 1, wherein the one end of one of the two adjacent metal wires is rectangular, and the one end of the other one of the two adjacent metal wires is in a form of a “C” to embrace the rectangular end.

7. The printed circuit board as claimed in claim 1, wherein a distance between the two adjacent metal wires is equal to or greater than 3 mils.

8. The printed circuit board as claimed in claim 1, wherein the metal wires are made of one material selected from a group consisting of copper, tin, nickel, titanium, and chromium.

9. The printed circuit board as claimed in claim 2, wherein the electrically-conductive layer is a solder layer.

10. The printed circuit board as claimed in claim 9, wherein the solder layer is made of one material selected from a group consisting of tin, tin-lead, tin-copper, tin-silver, and tin-silver-copper.

11. The printed circuit board as claimed in claim 2, wherein the electrically-conductive layer is formed by using a screen having an opening.
